(19) United States
(12) Patent Application Publication
(10) Pub. No.: US 2011/0080211 A1
(43) Pub. Date: Apr. 7, 2011

(54) Systems and Methods for Noise Reduced Data Detection

(76) Inventors: Shaohua Yang, Santa Clara, CA (US); Yuan Xing Lee, San Jose, CA (US); Richard Rauschmayer, Longmont, CO (US); Hongwei Song, Longmont, CO (US); Jingfeng Liu, Longmont, CO (US); Weijun Tan, Longmont, CO (US)

(21) Appl. No.: 12/992,948

(22) PCT Filed: Apr. 17, 2009
(86) PCT No.: PCT/US09/40986

§ 371 Date: Nov. 16, 2010

Related U.S. Application Data
(60) Provisional application No. 61/116,389, filed on Nov. 20, 2008.

(51) Int. Cl. H03K 5/00

(52) U.S. Cl. 327/551

(57) ABSTRACT

Various embodiments of the present invention provide systems and methods for data processing. For example, some embodiments of the present invention provide noise reduced data processing circuits. Such circuits include a selector circuit, a sample set averaging circuit, and a data detection circuit. The selector circuit provides either a new sample set or an averaged sample set as a sample output based on a select control signal. The sample set averaging circuit receives the new sample set and provides the averaged sample set. The averaged sample set is based upon two or more instances of the new sample set. The data detection circuit receives the sample output, and performs a data detection algorithm on the sample output and provides the select control signal and a data output.

### CROSS REFERENCE TO RELATED APPLICATIONS

The present application claims priority to (is a non-provisional of) U.S. Pat. App. No. 61/116,389 entitled “Systems and Methods for Noise Reduced Data Detection” and filed Nov. 20, 2008 by Yang et al. The entirety of the aforementioned provisional patent application is incorporated herein by reference for all purposes.

### BACKGROUND OF THE INVENTION

The present inventions are related to systems and methods for detecting and/or decoding information, and more particularly to systems and methods for reducing noise in the when detecting and/or decoding information.

Various data transfer systems have been developed including storage systems, cellular telephone systems, and radio transmission systems. In each of the systems data is transferred from a sender to a receiver via some medium. For example, in a storage system, data is sent from a sender (i.e., a write function) to a receiver (i.e., a read function) via a storage medium. The effectiveness of any transfer is impacted by any noise evident in the data being received from the medium. In some cases, the received signal exhibits a noise level that does not allow any downstream data detection process to converge. To heighten the possibility of convergence, various existing processes utilize two or more detection and decode iterations. However, even with such extended data detection capability, the noise included in the received signal may still preclude convergence.

Hence, for at least the aforementioned reasons, there exists a need in the art for advanced systems and methods for data processing.

### BRIEF SUMMARY OF THE INVENTION

The present inventions are related to systems and methods for detecting and/or decoding information, and more particularly to systems and methods for reducing noise in the when detecting and/or decoding information.

Various embodiments of the present invention provide noise reduced data processing circuits. Such circuits include a selector circuit, a sample set averaging circuit, and a data detection circuit. The selector circuit provides either a new sample set or an averaged sample set as a sample output based on a select control signal. The sample set averaging circuit receives the new sample set and provides the averaged sample set. The averaged sample set is based upon two or more instances of the new sample set. The data detection circuit receives the sample output, and performs a data detection algorithm on the sample output and provides the select control signal and a data output. Some instances of the aforementioned embodiments include a sample buffer that stores the sample output from the selector circuit, and provides the sample output to the data detection circuit. In particular instances, the sample set averaging circuit includes the sample buffer and an adder circuit. The adder circuit adds the new sample set to the sample output.

In various instances of the aforementioned embodiments, the sample buffer includes a divider circuit. The divider circuit divides the sample output by the number of instances of the new sample set included in the sample output, and the output of the divider circuit is provided to the data detection circuit as the sample output. In other instances of the aforementioned embodiments, the number of instances of the new sample set included in the sample output is a power of two. In such instances, a shift circuit divides the sample output by the number of instances of the new sample set included in the sample output. The output of the shift circuit is provided to the data detection circuit as the sample output.

In some instances of the aforementioned embodiments, the select control signal is asserted to select the averaged sample set as the sample output when the data detection circuit fails to converge when processing an initial instance of the new sample set. In various embodiments of the present invention, the data detection circuit includes a channel detector, and a low density parity check decoder. The channel detector receives the sample output, and an output of the channel detector is provided to the low density parity check decoder. In particular instance of the aforementioned embodiments, the data detection circuit further includes a soft/hard decision buffer. The data output is provided by the soft/hard decision buffer. In some embodiments of the present invention, the data detection circuit further includes an averaged retry logic circuit that receives an indication of whether the low density parity check decoder converged, and asserts the select control signal.

Other embodiments of the present invention provide methods for performing reduced noise data processing. Such methods include receiving a first instance of a new sample set, and performing a data detection on the new sample set. Where the data detection fails to converge, a second instance of the new sample set is received and a sample set average is performed. The sample set average includes adding at least the first instance of the new sample set with the second instance of the new sample set to create an averaged sample set. A data detection is then performed on the averaged sample set. In particular instances of the aforementioned embodiments, the methods further include receiving a third instance and a fourth instance of the new sample set.

Yet other embodiments of the present invention provide systems for selectively performing reduced noise data processing. The systems include a data input derived from a medium. The systems further include a data processing circuit that includes a selector circuit, a sample set averaging circuit, and a data detection circuit. The selector circuit provides either a new sample set or an averaged sample set as a sample output based on a select control signal. The sample set averaging circuit receives the new sample set and provides the averaged sample set. The averaged sample set is based upon two or more instances of the new sample set. The data detection circuit receives the sample output, and performs a data detection algorithm on the sample output and provides the select control signal and a data output. In some cases, the medium is a magnetic storage medium. In other instances, the medium is a transmission medium, such as, for example, a wireless transmission medium, a wired transmission medium, or an optical transmission medium.

This summary provides only a general outline of some embodiments of the invention. Many other objects, features, advantages and other embodiments of the invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIG. 1 depicts a data processing circuit including a noise reduction front end in accordance with various embodiments of the present invention;

FIG. 2 depicts another data processing circuit including a noise reduction front end in accordance with various embodiments of the present invention;

FIG. 3 is a flow diagram depicting a data processing approach in accordance with various embodiments of the present invention;

FIG. 4 is a data storage system including a read channel with a noise reduction front end in accordance with various embodiments of the present invention; and

FIG. 5 is a data transmission system including a receiver with a noise reduction front end in accordance with some embodiments of the present invention.

### DETAILED DESCRIPTION OF THE INVENTION

The present inventions are related to systems and methods for detecting and/or decoding information, and more particularly to systems and methods for reducing noise in the when detecting and/or decoding information.

Various embodiments of the present invention provide data processing circuits that reduce or eliminate the effects of read and/or write noise associated with a transferred data set. In some embodiments of the present invention, the noise reduction is selectively utilized. In such cases, the noise reduction may involve some level of latency. By selectively enabling the noise reduction, the latency is only incurred when necessary. In some embodiments of the present invention, the noise reduction is provided by multiply receiving a given set of data and averaging the multiple reads. This averaging process tends to reduce data independent noise that may have been introduced during transfer of the data set. The averaged data set is then provided for data detection where the noise reduction increases the probability that the data detection process will converge. In some embodiments, the noise reduction function is only selected after the non-averaged data set fails to converge.

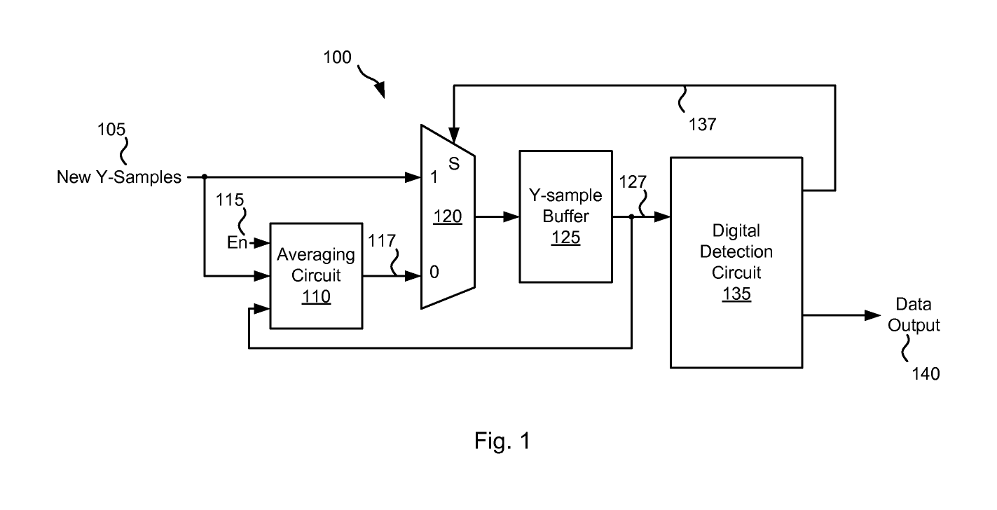

Turning to FIG. 1, a data processing circuit 100 is shown in accordance with some embodiments of the present invention that includes a noise reduction front end circuit 105. Noise reduction front end circuit 105 includes a multiplexer circuit 120 that is capable of selecting between a new sample input 103 and an averaged sample input 117 based upon a select control signal 137. New sample input 103 includes a number of samples of a data set. In some cases, new sample input 103 is derived from a magnetic storage medium. In other cases, new sample input 103 is derived from a transmission channel. Based on the disclosure provided herein, one of ordinary skill in the art will recognize a variety of sources for new sample input 103. Multiplexer circuit 120 provides a selected sample set (i.e., either new sample input 103 or averaged sample input 117) to a sample buffer 125. Sample buffer 125 provides a sample output 127 to a selective adder circuit 110. Averaged sample input 117 is generated by selective adder circuit 110 by averaging a number of instances of sample output 127 received from sample buffer 125. An enable input 115 controls resetting of the averaged output of selective adder circuit 110 by writing new sample input 103.

In addition, sample output 127 is provided to a digital detection circuit 135 that is responsible for decoding and/or detecting the information represented by sample output 127. Digital detection circuit 135 may be any detection/decoding circuit known in the art. For example, digital detection circuit 135 may include a channel detector feeding a low density parity check decoder as are known in the art. As another example, digital detection circuit 135 may include a channel detector feeding a Reed Solomon decoder as are known in the art. Based on the disclosure provided herein, one of ordinary skill in the art will recognize a myriad of decoder and/or detectors that may be used to implement digital detection circuit 135 in accordance with different embodiments of the present invention. Digital detection circuit 135 provides a data output 140.

In addition to the standard decoding and detection circuitry, digital detection circuit 135 is modified to provide select control signal 137 and enable input 115. Select control signal 137 and enable input 115 determines whether the noise reduction processes noise reduction front end circuit 105 are implemented in relation to a given data set. The following pseudo-code describes the operation of noise reduction front end circuit 105:

```
/* Setup Control of Noise Reduction Front End*/
If (Data Set Converged){
  -provide Data Output 140;
  -assert Select Control Signal 137 to select New Sample Input 103;
  -assert Enable Input 115 to cause New Sample Input 103 to be written to Selective
  adder circuit 110;
  -reset Count }
Else {
  /* No convergence after averaging attempted*/
  If (previous failure to converge) {
    -indicate non-retry error in Data Output 140;
    -assert Select Control Signal 137 to select New Sample Input 103;
    -assert Enable Input 115 to cause New Sample Input 103 to be written to
    Selective adder circuit 110;
    -reset Count }
  /* No convergence, but averaging not yet attempted*/
  Else {
    -indicate retry error in Data Output 140;
    -assert Select Control Signal 137 to select Averaged Sample Input 117;
    -assert Enable Input 115 to cause averaging of Sample Output 127 with
    New Sample Input 103 }}
/* Processing where data previously converged */
If (Select Control Signal is asserted to select New Sample Input 103) {
  -select next data to be read as New Sample Input 103;
  -provide New Sample Input 103 to Digital Detection Circuit 135;
  -perform data detection and/or decoding }
/* Processing where data failed to converge */
Else {
  /* Perform Averaging of Multiple Instances of Received Data Set*/
  For (Count = 0 to Count = Defined Count) {
    -select previously received data set to be re-read as New Sample Input
    103;
    -average New Sample Input 103 with Sample Output 127;
    -write averaged value to Sample Buffer 125;
    -increment Count }
  -provide Averaged Sample Input 117 to Digital Detection Circuit 135;
  -perform data detection and/or decoding }
```

Consistent with the preceding pseudo-code and the embodiment depicted in FIG. 1, whenever digital detection circuit 135 converges data output 140 is provided. Alternatively, where the averaging process of noise reduction front end circuit 105 has been used, but digital detection circuit 135 failed to converge, data output 140 is indicated as non-recoverable. In either case, select control signal 137 is asserted as a logic ‘1’ and enable input 115 is asserted such that new sample input 103 is written to selective adder circuit 110. In this setup, the next data set presented as new sample input 103 will be passed to sample buffer 125 via multiplexer 120, and then directly to digital detection circuit 135 where the detection and/or decoding processes are performed to derive data output 140. By doing this, an attempt to process each data set is made before the functionality of noise reduction front end circuit 105 is used and the associated latency is incurred. As such, latency associated with averaging multiple instances of a given data set is not incurred when not necessary.

Where, on the other hand, digital detection circuit 135 fails to converge when operating on a non-averaged data set, data output 140 is indicated as unavailable and potentially recoverable. In this situation, the previously processed data set is re-read a number of times (i.e., a number of times corresponding to “Defined Count” in the pseudo-code). Each time the data set is re-read, it is averaged with the other times the data set has been read. This process of averaging averages the re-read data sets together on a bit period by bit period basis resulting in an averaged data set of the same length as the originally received data set. This process of averaging reduces or eliminates any random read noise (i.e., non-data dependent noise exhibited by the data set). Once the defined number or re-reads and averaging is completed, averaged sample input 117 is provided to sample buffer 125 via multiplexer 120, and then to digital detection circuit 135 where the detection and/or decoding processes are performed to derive data output 140.

In some cases where data processing circuit 100 is implemented as part of a hard disk drive system, the data set that is processed on any iteration of data processing circuit 100 corresponds to a full sector of data. In other cases, the data set has a length less than or more than an entire sector. In particular cases, the data set may include a portion from one sector and a portion from another sector. Where, on the other hand, data processing circuit 100 is implemented as part of a data communication system, the length of the given data set may be pre-defined. Based upon the disclosure provided herein, one of ordinary skill in the art will recognize various data lengths that may be processed.

In one particular embodiment of the present invention, selective adder circuit 110 is implemented as an adder circuit. When enable input 115 is asserted such that new sample input 103 is to be written to selective adder circuit 110, the adder circuit adds each bit of new sample input 103 to a zero. This effectively results in a write of new sample input 103 to selective adder circuit 110. Alternatively, when enable input 115 is asserted such that averaging is to be performed, the adder circuit adds new sample input 103 to sample output 127 on a bit period by bit period basis. As new sample input 103 is another instance of sample output 127, noise in one instance may operate to cancel noise in another instance. As averaged output 117 is written to sample buffer 125, the combination of the adder circuit and sample buffer 125 operate as an accumulator. Prior to providing sample output 127 to digital detection circuit 135, the accumulated value is divided by the number of added samples to create an average. In some embodiments, a divider is employed as part of sample buffer 125 to finish the averaging process. In other cases, the number of averaged samples is a factor of two (i.e., 2ⁿ). In these cases, the average is obtained by using a shift function incorporated in sample buffer 125, where the amount of the shift corresponds to the number of averaged samples. In some embodiments, the averaging is performed by weighted addition. In these cases, the averaged output 117 and the new input 103 are multiplied by two weighting factors such that the sum of the weighting factors equals 1. The weighted sum of the averaged output 117 and the new input 103 is written into the sample buffer 125. Based upon the disclosure provided herein, one of ordinary skill in the art will recognize other circuitry that may be used to average a number of new samples 103.

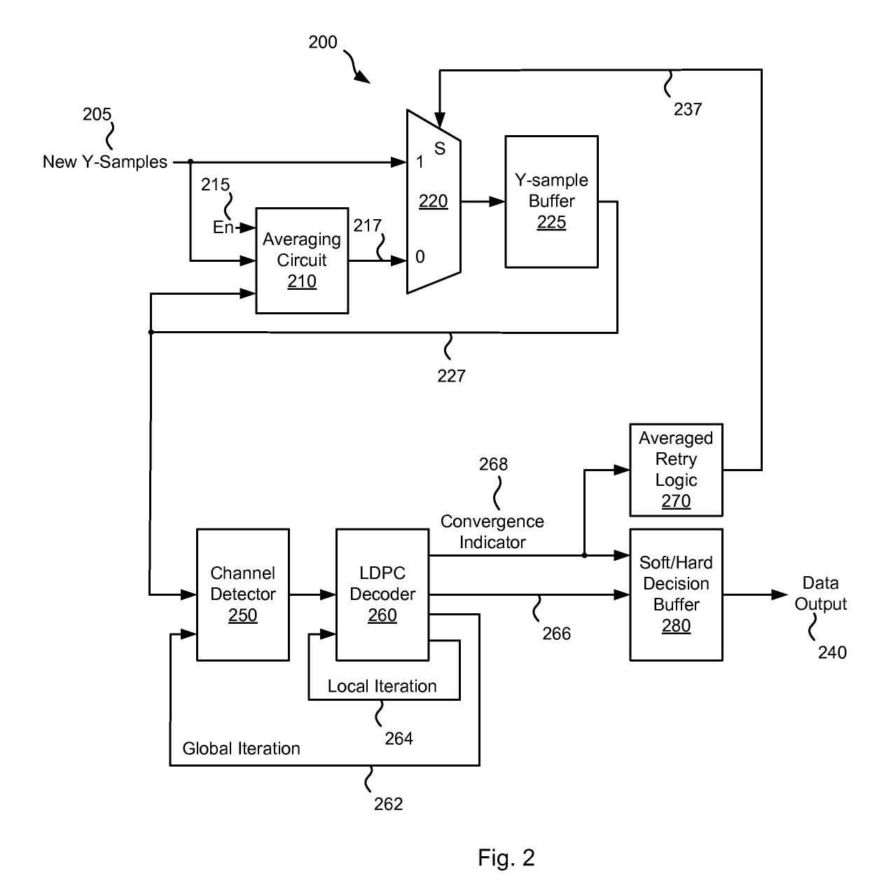

Turning to FIG. 2, a data processing circuit 200 is shown in accordance with some embodiments of the present invention that includes a noise reduction front end circuit 205. Noise reduction front end circuit 205 includes a multiplexer circuit 220 that is capable of selecting between a new sample input 203 and an averaged sample input 217 based upon a select control signal 237. New sample input 203 includes a number of samples of a data set. In some cases, new sample input 203 is derived from a magnetic storage medium. In other cases, new sample input 203 is derived from a transmission channel. Based on the disclosure provided herein, one of ordinary skill in the art will recognize a variety of sources for new sample input 203. Multiplexer circuit 220 provides a selected sample set (i.e., either new sample input 203 or averaged sample input 217) to a sample buffer 225. Sample buffer 225 provides a sample output 227 to a selective adder circuit 210. Averaged sample input 217 is generated by selective adder circuit 210 by averaging a number of instances of sample output 227 received from sample buffer 225. An enable input 215 controls resetting of the averaged output of selective adder circuit 210 by writing new sample input 203.

In addition, sample output 227 is provided to a channel detector 250 that performs a detection process and provides a series of hard outputs and soft outputs to a low density parity check decoder 260. Low density parity check decoder 260 may perform one or more local iterations 264 where the result of a prior low density parity check feeds back to perform another low density parity check as is known in the art. In some cases, one or more global iterations 262 may be performed where the result of a prior low density parity check feeds back to perform another iteration of channel detector 250 and low density parity checking as is known in the art. Low density parity check decoder 260 provides a data output to a soft/hard decision buffer 280 as is known in the art. Soft/hard decision buffer 280 provides a data output 240.

In addition to the standard decoding circuitry, low density parity check decoder 260 indicates whether low density parity check decoder 260 converged. Where the result converges, a convergence indicator 268 is asserted. Otherwise, convergence indicator 268 is de-asserted. An averaged retry logic circuit 270 receives convergence indicator 268, and provides select control signal 237 and enable input 215. Select control signal 237 and enable input 215 determines whether the noise reduction processes noise reduction front end circuit 205 are implemented in relation to a given data set. The following pseudo-code describes the operation of noise reduction front end circuit 205:

```
/* Setup Control of Noise Reduction Front End*/
If (Convergence Indicator is Asserted){
  -provide Data Output 240;
  -assert Select Control Signal 237 to select New Sample Input 203;
  -assert Enable Input 215 to cause New Sample Input 203 to be written to Selective
  adder circuit 210;
  -reset Count }
Else {
  /* No convergence after averaging attempted*/
  If (previous failure to converge) {
    -withhold Data Output 240;
    -assert Select Control Signal 237 to select New Sample Input 203;
    -assert Enable Input 215 to cause New Sample Input 203 to be written to
    Selective adder circuit 210;
    -reset Count }
  /* No convergence, but averaging not yet attempted*/
  Else {
    -withhold Data Output 240;
    -assert Select Control Signal 237 to select Averaged Sample Input 217;
    -assert Enable Input 215 to cause averaging of Sample Output 227 with
    New Sample Input 203 }}
/* Processing where data previously converged */
If (Select Control Signal is asserted to select New Sample Input 203) {
  -select next data to be read as New Sample Input 203;
  -provide New Sample Input 203 to Digital Detection Circuit 235;
  -perform data detection and decoding }
/* Processing where data failed to converge */
Else {
  /* Perform Averaging of Multiple Instances of Received Data Set*/
  For (Count = 0 to Count = Defined Count) {
    -select previously received data set to be re-read as New Sample Input
    203;
    -average New Sample Input 203 with Sample Output 227;
    -write averaged value to Sample Buffer 225;
    -increment Count }
  -provide Averaged Sample Input 217 to Digital Detection Circuit 235;
  -perform data detection and decoding }
```

Consistent with the preceding pseudo-code and the embodiment depicted in FIG. 2, whenever low density parity check decoder 260 converges data output 240 is provided. Alternatively, where the averaging process of noise reduction front end circuit 205 has been used, but low density parity check decoder 260 failed to converge, data output 240 is indicated as non-recoverable. In either case, select control signal 237 is asserted as a logic ‘1’ and enable input 215 is asserted such that new sample input 203 is written to selective adder circuit 210. In this setup, the next data set presented as new sample input 203 will be passed to sample buffer 225 via multiplexer 220, and then directly to channel detector 250 where the detection and/or decoding processes are performed to derive data output 240. By doing this, an attempt to process each data set is made before the functionality of noise reduction front end circuit 205 is used and the associated latency is incurred. As such, latency associated with averaging multiple instances of a given data set is not incurred when not necessary.

Where, on the other hand, low density parity check decoder 260 fails to converge when operating on a non-averaged data set, data output 240 is indicated as unavailable and potentially recoverable. In this situation, the previously processed data set is re-read a number of times (i.e., a number of times corresponding to “Defined Count” in the pseudo-code). Each time the data set is re-read, it is averaged with the other times the data set has been read. This process of averaging averages the re-read data sets together on a bit period by bit period basis resulting in an averaged data set of the same length as the originally received data set. This process of averaging reduces or eliminates any random noise (i.e., non-data dependent noise exhibited by the data set). Once the defined number or re-reads and averaging is completed, averaged sample input 217 is provided to sample buffer 225 via multiplexer 220, and then to channel detector 250 and low density parity check decoder 260 where the detection and decoding processes are performed to derive data output 240.

In some cases where data processing circuit 200 is implemented as part of a hard disk drive system, the data set that is processed on any iteration of data processing circuit 200 corresponds to a full sector of data. In other cases, the data set has a length less than or more than an entire sector. In particular cases, the data set may include a portion from one sector and a portion from another sector. Where, on the other hand, data processing circuit 200 is implemented as part of a data communication system, the length of the given data set may be pre-defined. Based upon the disclosure provided herein, one of ordinary skill in the art will recognize various data lengths that may be processed.

In one particular embodiment of the present invention, selective adder circuit 210 is implemented as an adder circuit. When enable input 215 is asserted such that new sample input 203 is to be written to selective adder circuit 210, the adder circuit adds each bit of new sample input 203 to a zero. This effectively results in a write of new sample input 203 to selective adder circuit 210. Alternatively, when enable input 215 is asserted such that averaging is to be performed, the adder circuit adds new sample input 203 to sample output 227 on a bit period by bit period basis. As new sample input 203 is another instance of sample output 227, noise in one instance may operate to cancel noise in another instance. As averaged output 217 is written to sample buffer 225, the combination of the adder circuit and sample buffer 225 operate as an accumulator. Prior to providing sample output 227 to channel detector 250 and low density parity check decoder 260, the accumulated value is divided by the number of added samples to create an average. In some embodiments, a divider is employed as part of sample buffer 225 to finish the averaging process. In other cases, the number of averaged samples is a factor of two (i.e., 2ⁿ). In these cases, the average is obtained by using a shift function incorporated in sample buffer 225, where the amount of the shift corresponds to the number of averaged samples. Also in some embodiments, the averaging is obtained by computing the weighted sum of the new sample input 203 and the sample output 227, where the weighting factors are programmable and sum up to 1. In these cases, a divider is avoided and the samples stored in Y sample buffer 225 can have less bit width than using an accumulator and divider. Based upon the disclosure provided herein, one of ordinary skill in the art will recognize other circuitry that may be used to average a number of new samples 203.

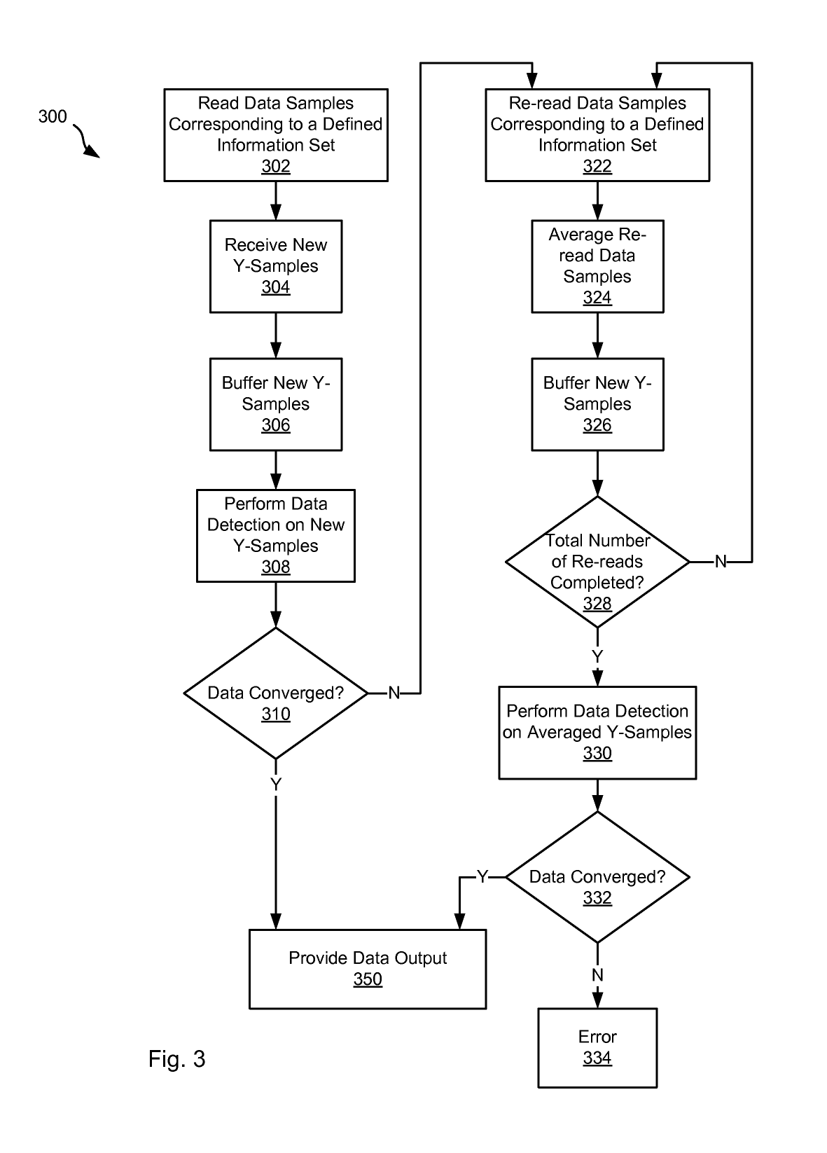

Turning to FIG. 3, a flow diagram 300 depicts a data processing approach in accordance with various embodiments of the present invention. Following flow diagram 300, data corresponding to a defined information set are read (block 302). This may include, for example, sensing information from a magnetic storage medium and providing that information as a series of digital samples. These data samples are received as a new sample input (block 304). The received new sample input is buffered (block 306) and a data detection process is performed on the newly received data samples (block 308). The data detection process may be performed in accordance with any data detection/decoder process known in the art. In one particular case, the data detection process includes performing a channel detect process followed by a low density parity check decode process as are known in the art.

It is determined whether the data detection process converged (block 310). Where the data detection process converged (block 310), the data output is provided as an output (block 350). Then, the data corresponding to the next defined information set are read (block 302) and the processes of blocks 304-310 are repeated for the next data input.

Alternatively, where the data detection process failed to converge (block 310), the data corresponding to the defined data set is re-read (block 322). This may include, for example, performing the same process as block 302 on the same data set previously read. This newly read data set is averaged with the originally read data set (or with the averaged data sets for the second or later read) (block 324) and the resulting average is stored to a sample buffer (block 326). It is then determined whether a programmed number of re-reads have been averaged together (block 328). Where the programmed number of re-reads has not been completed (block 328), the defined information set is again re-read (block 322) and the processes of blocks 324-328 are repeated for the newly read data samples.

Alternatively, where the programmed number of re-reads has been incorporated in the average (block 328), the data detection process is performed on the averaged samples (block 330). The data detection process is the same data detection process previously discussed in relation to block 308, except that the input to the process is an averaged sample set. It is determined whether the data detection process converged (block 332). Where the data detection process converged (block 332), the data output is provided as an output (block 350). Then, the data corresponding to the next defined information set are read (block 302) and the processes of blocks 304-310 are repeated for the next data input. Alternatively, where the data detection process failed to converge (block 332), an error is indicated (block 334). Then, the data corresponding to the next defined information set are read (block 302) and the processes of blocks 304-310 are repeated for the next data input.

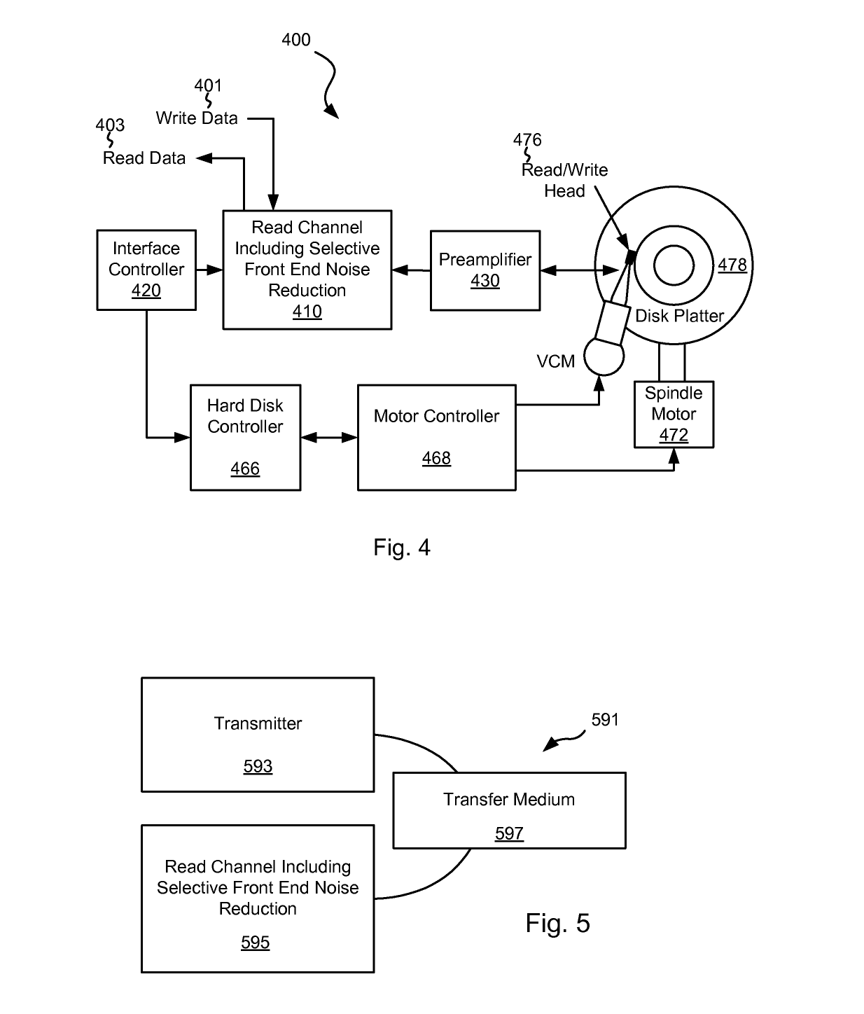

Turning to FIG. 4, a data storage system 400 is shown in accordance with various embodiments of the present invention. Data storage system 400 may be, for example, a hard disk drive. Data storage system 400 includes a read channel 410 with a noise reduction front end. The incorporated noise reduction front end may be any noise reduction front end capable of reducing noise evident in the received signal. In some embodiments of the present invention, read channel 410 is implemented similar to that discussed above in relation to FIG. 1. Read channel 410 receives information obtained from a disk platter 478 via a read/write head assembly 476 and a preamplifier 430. In addition, data storage system 400 includes an interface controller 420, a hard disk controller 466, a motor controller 468, and a spindle motor 472. Interface controller 420 controls addressing and timing of data to/from disk platter 478. The data on disk platter 478 consists of groups of magnetic signals that may be detected by read/write head assembly 476 when the assembly is properly positioned over disk platter 478. In a typical read operation, read/write head assembly 476 is accurately positioned by motor controller 468 over a desired data track on disk platter 478. Motor controller 468 both positions read/write head assembly 476 in relation to disk platter 478 and drives spindle motor 472 by moving read/write head assembly 476 to the proper data track on disk platter 478 under the direction of hard disk controller 466. Spindle motor 472 spins disk platter 478 at a determined spin rate (RPMs).

Once read/write head assembly 476 is positioned adjacent the proper data track, magnetic signals representing data on disk platter 478 are sensed by read/write head assembly 476 as disk platter 478 is rotated by spindle motor 472. The sensed magnetic signals are provided as a continuous, minute analog signal representative of the magnetic data on disk platter 478. This minute analog signal is transferred from read/write head assembly 476 to read channel module 410 via preamp 430. Preamp 430 is operable to amplify the minute analog signals accessed from disk platter 478. In addition, preamp 430 is operable to amplify data from read channel module 410 that is destined to be written to disk platter 478. In turn, read channel module 410 decodes and digitizes the received analog signal to recreate the information originally written to disk platter 478. Where the data fails to converge, it may be re-read multiple times and an average of the re-read data may then be decoded and digitized as discussed above in relation to FIG. 1. The decoded data is provided as read data 403 to a receiving circuit. A write operation is substantially the opposite of the preceding read operation with write data 401 being provided to read channel module 410. This data is then encoded and written to disk platter 478.

Turning to FIG. 5, a communication system 591 including a receiver 595 with a selective front end noise reduction circuit is shown in accordance with one or more embodiments of the present invention is shown. Communication system 591 includes a transmitter 593 that is operable to transmit encoded information via a transfer medium 597 as is known in the art. The encoded data is received from transfer medium 597 by receiver 595. Receiver 595 incorporates a data processing system similar to that discussed above in relation to FIG. 1 and is operable to decode the transferred information. Where transfer across transfer medium introduces too much noise in the received data, the data detection process of receiver 595 may not be capable of deriving the intended information. In such a case, one or more additional transmissions of the information may be requested from transmitter 593. These are averaged with the originally received transmission such that non-data dependent noise in the transmission is averaged out. This averaged signal is then re-processed using the data decoding processes of receiver 595. It should be noted that transfer medium 597 may be any medium whereby information is transferred including, but not limited to, a wired interface, an optical interface, a wireless interface, and/or combinations thereof. Based on the disclosure provided herein, one of ordinary skill in the art will recognize a variety of mediums that may include defects and that may be utilized in relation to different embodiments of the present invention.

In conclusion, the invention provides novel systems, devices, methods and arrangements for performing noise reduced data decoding and/or detection. While detailed descriptions of one or more embodiments of the invention have been given above, various alternatives, modifications, and equivalents will be apparent to those skilled in the art without varying from the spirit of the invention. For example, one or more embodiments of the present invention may be applied to various data storage systems and digital communication systems, such as, for example, tape recording systems, optical disk drives, wireless systems, and digital subscribe line systems. Therefore, the above description should not be taken as limiting the scope of the invention, which is defined by the appended claims.

What is claimed is:

1. A noise reduced data processing circuit, the circuit comprising:
a selector circuit, wherein the selector circuit provides either a new sample set or an averaged sample set as a sample output based on a select control signal;
a sample set averaging circuit, wherein the sample set averaging circuit receives the new sample set and provides the averaged sample set, and wherein the averaged sample set is based upon two or more instances of the new sample set; and
a data detection circuit, wherein the data detection circuit receives the sample output, and wherein the data detection circuit performs a data detection algorithm on the sample output and provides the select control signal and a data output.

2. The circuit of claim 1, wherein the circuit further comprises:
a sample buffer, wherein the sample buffer stores the sample output from the selector circuit, and wherein the sample buffer provides the sample output to the data detection circuit.

3. The circuit of claim 1, wherein the sample set averaging circuit includes:
a sample buffer, wherein the sample buffer stores the sample output from the selector circuit, and wherein the sample buffer provides the sample output to the data detection circuit; and
an adder circuit, wherein the adder circuit adds the new sample set to the sample output.

4. The circuit of claim 3, wherein the sample buffer includes a divider circuit, and wherein the divider circuit divides the sample output by the number of instances of the new sample set included in the sample output, and wherein the output of the divider circuit is provided to the data detection circuit as the sample output.

5. The circuit of claim 3, wherein the number of instances of the new sample set included in the sample output is a power of two, wherein a shift circuit divides the sample output by the number of instances of the new sample set included in the sample output, and wherein the output of the shift circuit is provided to the data detection circuit as the sample output.

6. The circuit of claim 1, wherein the select control signal is asserted to select the averaged sample set as the sample output when the data detection circuit fails to converge when processing an initial instance of the new sample set.

7. The circuit of claim 1, wherein the data detection circuit includes:
a channel detector; and
a low density parity check decoder, wherein the channel detector receives the sample output, and wherein an output of the channel detector is provided to the low density parity check decoder.

8. The circuit of claim 7, wherein the data detection circuit further includes a soft/hard decision buffer, and wherein the data output is provided by the soft/hard decision buffer.

9. The circuit of claim 7, wherein the data detection circuit further includes an averaged retry logic circuit, wherein the averaged retry logic circuit receives an indication of whether the low density parity check decoder converged, and wherein the averaged retry logic circuit asserts the select control signal.

10. A method for performing reduced noise data processing, the method comprising:
receiving a first instance of a new sample set;
performing a data detection on the new sample set, wherein the data detection failed to converge;
receiving a second instance of the new sample set;
performing a sample set average, wherein the sample set average includes adding at least the first instance of the new sample set with the second instance of the new sample set to create an averaged sample set; and
performing a data detection on the averaged sample set.

11. The method of claim 10, wherein the data detection includes performing a channel detection and a low density parity check decode.

12. The method of claim 10, wherein the method further comprises:
receiving a third instance of the new sample set;
receiving a fourth instance of the new sample set; and
wherein the sample set average includes adding the first instance of the new sample set, the second instance of the new sample set, the third instance of the new sample set, and the fourth instance of the new sample set; and dividing by four to create the averaged sample set.

13. A system for selectively performing reduced noise data processing, the system comprising:
a data input, wherein the data input is derived from a medium;
a data processing circuit, wherein the data processing circuit includes:
a selector circuit, wherein the selector circuit provides either a new sample set or an averaged sample set as a sample output based on a select control signal;
a sample set averaging circuit, wherein the sample set averaging circuit receives the new sample set and provides the averaged sample set, and wherein the averaged sample set is based upon two or more instances of the new sample set; and
a data detection circuit, wherein the data detection circuit receives the sample output, and wherein the data detection circuit performs a data detection algorithm on the sample output and provides the select control signal and a data output.

14. The system of claim 13, wherein the medium is a magnetic storage medium.

15. The system of claim 13, wherein the medium is a transmission medium.

16. The system of claim 15, wherein the transmission medium is selected from a group consisting of: a wireless transmission medium, a wired transmission medium, and an optical transmission medium.

17. The system of claim 13, wherein the sample set averaging circuit includes:
a sample buffer, wherein the sample buffer stores the sample output from the selector circuit, and wherein the sample buffer provides the sample output to the data detection circuit; and
an adder circuit, wherein the adder circuit adds the new sample set to the sample output.

18. The system of claim 17, wherein the sample buffer includes a divider circuit, and wherein the divider circuit divides the sample output by the number of instances of the new sample set included in the sample output, and wherein the output of the divider circuit is provided to the data detection circuit as the sample output.

19. The system of claim 17, wherein the number of instances of the new sample set included in the sample output is a power of two, wherein the shift circuit divides the sample output by the number of instances of the new sample set included in the sample output, and wherein the output of the shift circuit is provided to the data detection circuit as the sample output.

20. The system of claim 13, wherein the select control signal is asserted to select the averaged sample set as the sample output when the data detection circuit fails to converge when processing an initial instance of the new sample set.
